(19) United States
(12) Patent Application Publication
(10) Pub. No.: US 2026/0113024 A1
(43) Pub. Date: Apr. 23, 2026

(54) MANUFACTURING METHOD, PULSE DETECTOR, AND X RAY PHOTOELECTRON SPECTROSCOPY APPARATUS

(71) Applicant: SHIMADZU CORPORATION, Kyoto-shi (JP)

(72) Inventors: Kanta AKATSUKA, Kyoto-shi (JP); Eizo KAWATO, Kyoto-shi (JP)

(21) Appl. No.: 19/353,031

(22) Filed: Oct. 8, 2025

(30) Foreign Application Priority Data
Oct. 18, 2024 (JP) 2024-184083

(51) Int. Cl. H03K 5/24; G01N 23/2273; H03K 5/1254; H03K 5/14; H03K 5/1536

(52) U.S. Cl. CPC H03K 5/24; G01N 23/2273; H03K 5/1254; H03K 5/14; H03K 5/1536; G01N 2223/304

(57) ABSTRACT

A manufacturing method of a CFD circuit according to the present disclosure includes a step of providing a hysteresis comparator that includes two input terminals for receiving a delayed signal and an attenuated signal, has a first threshold and a second threshold, outputs a first output when a difference between voltage values input to the two input terminals is greater than or equal to the first threshold, and outputs a second output when the difference between the voltage values input to the two input terminals is less than or equal to the second threshold; a step of providing a voltage supply unit that applies an offset voltage to the hysteresis comparator; and a step of setting the offset voltage.

### TECHNICAL FIELD

The present disclosure relates to a manufacturing method, a pulse detector, and an X-ray photoelectron spectroscopy apparatus, and more particularly, to reducing the manufacturing cost of a CFD (Constant Fraction Discriminator) circuit that detects pulses of electrons and radiation.

### BACKGROUND ART

Surface analysis is an analysis that clarifies the structure and composition of the surface and interface of a sample by applying a stimulus to the sample and analyzing the detected response. As a method of surface analysis, for example, there is X-ray photoelectron spectroscopy (XPS), as disclosed in Japanese Unexamined Patent Application Publication No. 2001-201470 (Patent Literature 1).

In surface analysis, including XPS, a CFD circuit may be used to detect pulsed radiation or electrons emitted from a sample. The CFD circuit compares the value of a signal obtained by delaying an input pulse with the value of a signal obtained by attenuating the pulse, and detects the timing at which the magnitude relationship between these two values reverses. This allows for the detection of the timing at which the pulse amplitude reaches a constant fraction, regardless of the pulse amplitude. A comparator is used to compare the values of the two signals.

### Citation List

### Patent Literature

[Patent Literature 1] Japanese Unexamined Patent Application Publication No. 2001-201470

### SUMMARY OF INVENTION

### Technical Problem

By using a CFD circuit, it is possible to detect the timing at which the pulse amplitude reaches a constant fraction, regardless of the amplitude of the radiation or electron pulses. Specifically, a pulse is detected in response to an output from a comparator indicating that the voltage values of two input signals have become equal. Therefore, even when no pulse is being input, the voltage values at the two terminals of the comparator may become equal, and it may be processed as if a pulse has been detected, despite no pulse being input.

By applying an offset voltage to one of the input terminals, it is possible to prevent the voltages applied to the two input terminals of the comparator from becoming equal when no pulse is being input. However, when a pulse is input, the timing at which the pulse is detected shifts from the timing at which the value of the delayed signal of the input pulse and the value of the attenuated signal of the pulse become equal, by an amount corresponding to the value of the offset voltage.

Furthermore, by providing a circuit for determining whether a pulse has been input, it is possible to prevent the process from treating it as a detected pulse even if the voltages applied to the two input terminals become equal when no pulse is being input. By using a circuit for determining whether a pulse has been input, a pulse can be detected only when a pulse is input and the voltage values at the two terminals of the comparator become equal. Therefore, it is possible to prevent the erroneous processing of a pulse being detected when no pulse is being input, and no deviation occurs between the timing at which the voltage values of the two terminals become equal and the timing at which the pulse amplitude reaches a constant fraction. However, it is necessary to provide a separate circuit for determining whether a pulse has been input, in addition to the CFD circuit, which may increase the manufacturing cost of the CFD circuit.

The present disclosure has been made in view of such circumstances, and an object thereof is to reduce the manufacturing cost of a CFD circuit in which a detection signal is output at the timing when an input pulse amplitude reaches a constant fraction.

### Solution to Problem

A manufacturing method according to an aspect of the present disclosure is a method for manufacturing a CFD circuit that detects pulses of electrons or radiation, the method comprising: a step of providing a delayed signal generation unit that generates a delayed signal by delaying a pulse by a predetermined time; a step of providing an attenuated signal generation unit that generates an attenuated signal by attenuating the pulse by a predetermined fraction; a step of providing a hysteresis comparator that includes two input terminals for receiving the delayed signal and the attenuated signal, has a first threshold and a second threshold smaller than the first threshold, outputs a first output when a difference between voltage values input to the two input terminals is greater than or equal to the first threshold, and outputs a second output when the difference between the voltage values input to the two input terminals is less than or equal to the second threshold; a step of providing a voltage supply unit that applies an offset voltage corresponding to the first threshold or the second threshold to the hysteresis comparator; and a step of setting the offset voltage, wherein the step of setting the offset voltage includes setting a voltage corresponding to the first threshold as the offset voltage when the delayed signal is input to a non-inverting input terminal of the two input terminals in the CFD circuit, and setting a voltage corresponding to the second threshold as the offset voltage when the delayed signal is input to an inverting input terminal of the two input terminals in the CFD circuit.

### Advantageous Effects of Invention

According to the present disclosure, it is possible to reduce the manufacturing cost of a CFD circuit in which a detection signal is output at the timing when an input pulse amplitude reaches a constant fraction.

### BRIEF DESCRIPTION OF DRAWINGS

FIG. 1 is a schematic diagram showing the configuration of an XPS according to the present embodiment.

FIG. 2 is a schematic diagram showing the configuration of a detector according to the present embodiment.

FIG. 3 is a schematic diagram showing the configuration of a CFD according to the present embodiment.

FIG. 4 is a diagram for explaining a signal output from a hysteresis comparator.

FIG. 5 is a schematic diagram showing the configuration of a processing apparatus according to the present embodiment.

FIG. 6 is a diagram for explaining a method of detecting a pulse by setting a threshold according to a comparative example.

FIG. 7 is a diagram for explaining a method of detecting a pulse using a CFD circuit.

FIG. 8 is a schematic diagram showing the configuration of a CFD according to a comparative example.

FIG. 9 is a flowchart of a process related to the manufacturing of a CFD circuit.

FIG. 10 is a diagram for explaining the difference between the two thresholds of a hysteresis comparator.

### DESCRIPTION OF EMBODIMENTS

Hereinafter, embodiments of the present disclosure will be described in detail with reference to the drawings. In the drawings, the same or corresponding parts are denoted by the same reference numerals, and a description thereof will not be repeated.

A CFD circuit is used for detecting pulsed radiation or electrons emitted from a sample. In the description of the present embodiment, an XPS apparatus provided with a CFD circuit is taken as an example, but the apparatus to which the CFD circuit according to the present disclosure is applied is not limited to an XPS apparatus, and may be any device that detects pulses of radiation or electrons.

### Configuration of X-ray Photoelectron Spectroscopy Apparatus

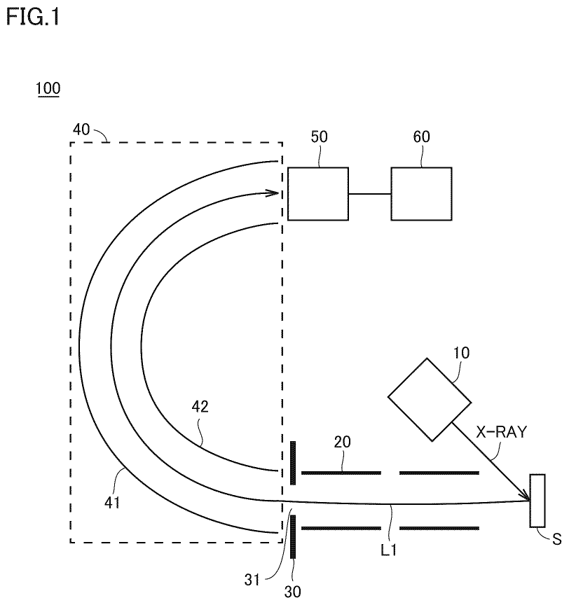

FIG. 1 is a diagram showing the configuration of an XPS apparatus 100 according to the embodiment. The XPS apparatus 100 measures the kinetic energy distribution of photoelectrons emitted by irradiating a sample S with X-rays, and acquires information regarding the types, abundance, and chemical bonding states of elements present on the surface of the sample S. With reference to FIG. 1, the XPS apparatus 100 includes an X-ray source 10, a lens 20, a slit 30, an energy spectrometer 40, a detector 50, and a processing apparatus 60.

The X-ray source 10 is configured to generate X-rays and irradiate the sample S with the generated X-rays. The X-ray source 10 includes, for example, a filament and an anode plate. The anode plate is formed of a metal material such as, for example, aluminum, magnesium, chromium, or copper. When a voltage is applied to the filament, thermionic electrons are emitted from the filament. The thermionic electrons are accelerated by a voltage applied between the filament and the anode plate. X-rays are generated from the anode plate when the accelerated thermionic electrons collide with the anode plate. When the sample S is irradiated with the generated X-rays, inner-shell electrons of elements present near the surface of the sample S are excited, and photoelectrons are emitted. Note that the electrons emitted from the sample S are not limited to photoelectrons, and may be Auger electrons. In FIG. 1, line L1 indicates the movement of electrons emitted from the sample S.

The lens 20 receives the electrons emitted from the sample S, and decelerates and converges the electrons. The lens 20 includes, for example, an electrostatic lens and a retardation lens. The electrostatic lens focuses the electrons onto an entrance slit 31 of the slit 30. The retardation lens decelerates the electrons incident on the energy spectrometer 40.

The energy spectrometer 40 spatially separates electrons according to the kinetic energy of the electrons emitted from the sample S. The energy spectrometer 40 includes an outer hemispherical electrode 41 and an inner hemispherical electrode 42. The energy spectrometer 40 applies a voltage to the outer hemispherical electrode 41 and the inner hemispherical electrode 42 to generate an electric field between the outer hemispherical electrode 41 and the inner hemispherical electrode 42. This electric field bends the flight path of the electrons that have passed through the slit 30. The electrons that have passed through the energy spectrometer 40 are incident on the detector 50. The potential difference between the outer hemispherical electrode 41 and the inner hemispherical electrode 42 corresponds to the kinetic energy of the electrons that can pass through the energy spectrometer 40. In FIG. 1, the energy spectrometer 40 is an electrostatic hemispherical electron energy spectrometer, but the energy spectrometer 40 is not limited to an electrostatic hemispherical electron energy spectrometer as long as it spatially separates incident electrons according to their kinetic energy.

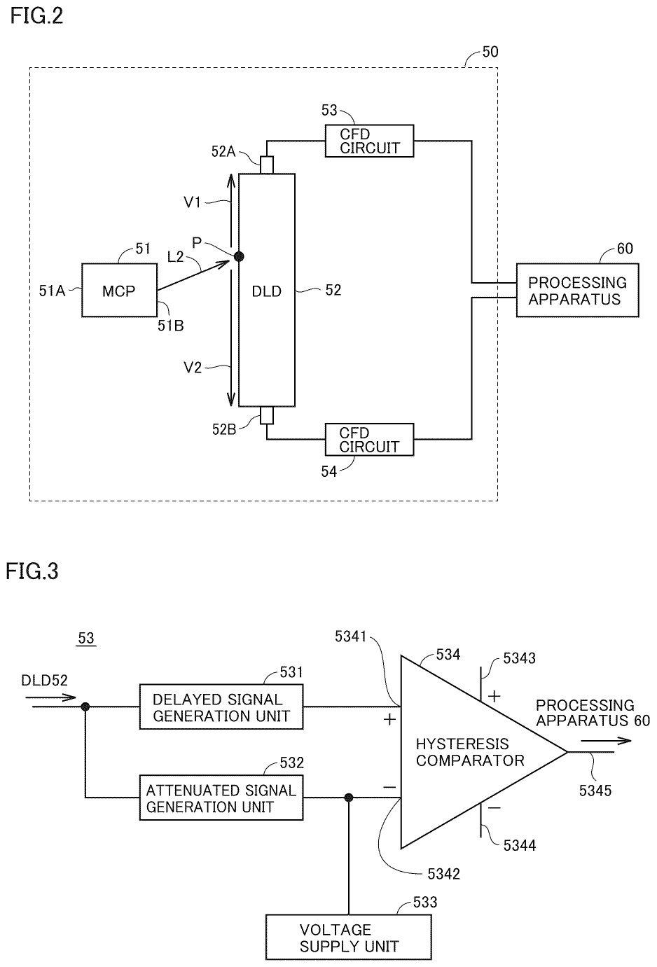

The detector 50 detects the electrons that have passed through the energy spectrometer 40. By adjusting the potential difference between the outer hemispherical electrode 41 and the inner hemispherical electrode 42, the kinetic energy of the electrons that can pass through the energy spectrometer 40 is changed. FIG. 2 is a diagram for explaining the configuration of the detector 50. With reference to FIG. 2, the detector 50 includes a micro-channel plate (MCP) 51, a delay line detector (DLD) 52, and CFD (Constant Fraction Discriminator) circuits 53 and 54.

The MCP 51 has a structure in which minute photomultiplier tubes are bundled, and amplifies incident charged particles. Specifically, electrons incident from an incident surface 51A are amplified by the MCP 51. Then, a plurality of electrons are emitted from an output surface 51B.

The DLD 52 detects the position of the electrons emitted from the MCP 51. The DLD 52 has a structure in which a conducting wire is wound. When an electron emitted from the MCP 51 collides with the conducting wire, charge flows from the collision position toward both ends of the wire. The time it takes for the charge to reach both ends of the wire differs depending on the position of the electron collision. Specifically, the charge reaches the end of the wire closer to the electron collision position earlier than the end of the wire farther from the electron collision position. For example, when an electron emitted from the output surface 51B strikes a position P on the DLD 52, a charge V1 travels toward a terminal 52A of the DLD 52, and a charge V2 travels toward a terminal 52B on the opposite side of the terminal 52A. The difference in the arrival times of the charges becomes information indicating the position of the electron collision.

By including the DLD 52 in the detector 50, it is possible to measure the position at which the electrons that have passed through the energy spectrometer 40 are incident on the detector 50. This can improve the resolution in the measurement of the kinetic energy of the electrons that have passed through the energy spectrometer 40. Specifically, by measuring the collision position of the electrons on the DLD 52 after passing through the energy spectrometer 40, the resolution of the measurement of the kinetic energy of the electrons can be improved, compared to simply counting the electrons that have passed through the energy spectrometer 40 in a state where a predetermined potential difference is generated.

The CFD circuits 53 and 54 are circuits used to detect pulses of electrons or radiation. Specifically, the CFD circuits 53 and 54 can output a detection signal at a timing when the pulse amplitude reaches a constant fraction, regardless of the amplitude of the input pulse. In the present specification, the detection signal refers to a signal output from a comparator to indicate that a pulse has been detected, and when the processing apparatus 60 receives this signal, it determines that a pulse has been detected. In the CFD circuits 53 and 54 in one embodiment, the switching of a Low signal to a High signal corresponds to outputting a detection signal, as will be described later.

The detector 50 according to the present embodiment can improve the resolution in the measurement of the kinetic energy of electrons by accurately detecting the position of electron incidence with the DLD 52. The position of electron incidence is detected by the difference in the arrival times of charges traveling toward both ends of the DLD 52 when an electron collides with the DLD 52. Therefore, it is necessary to output a detection signal at a predetermined timing regardless of the amplitude for the voltage pulses applied to the terminals 52A and 52B. CFD circuits 53 and 54 are used to output a detection signal regardless of the amplitude of the voltage pulses applied to the terminals 52A and 52B.

Note that the amplitudes of the pulse traveling toward the terminal 52A and the pulse traveling toward the terminal 52B, which are generated when an electron collides at position P on the DLD 52, are not necessarily the same. Therefore, in order to accurately measure the arrival timing of these pulses, a CFD circuit that can detect pulses regardless of their amplitude is required.

FIG. 3 is a diagram schematically showing the configuration of the CFD circuit 53 according to the present embodiment. Note that since the CFD circuit 54 has the same configuration as the CFD circuit 53, a detailed description thereof is omitted. With reference to FIG. 3, the CFD circuit 53 includes a delayed signal generation unit 531, an attenuated signal generation unit 532, a voltage supply unit 533, and a hysteresis comparator 534.

The delayed signal generation unit 531 generates a pulse by delaying an input pulse by a predetermined time. The predetermined time may be determined in advance or may be determined for each sample.

The attenuated signal generation unit 532 generates a pulse by attenuating an input pulse by a predetermined fraction. The predetermined fraction may be determined in advance or may be determined for each sample.

The voltage supply unit 533 supplies an offset voltage. The supplied offset voltage is applied to the pulse generated by the attenuated signal generation unit 532. The offset voltage is set to be equal to the voltage value of the first threshold of the hysteresis comparator 534. The voltage supply unit 533 is, for example, a DAC (Digital to Analog Converter). The offset voltage supplied from the voltage supply unit 533 will be described later.

The hysteresis comparator 534 is an element that compares two input voltage values and whose output switches depending on their magnitude relationship, and has a first threshold and a second threshold with a value smaller than the first threshold. The hysteresis comparator 534 has a non-inverting input terminal 5341, an inverting input terminal 5342, a positive power supply terminal 5343, a negative power supply terminal 5344, and an output terminal 5345. The pulse generated by the delayed signal generation unit 531 is input to the non-inverting input terminal 5341. A voltage value that is a composite of the pulse generated by the attenuated signal generation unit 532 and the voltage supplied by the voltage supply unit 533 is input to the inverting input terminal 5342. Power for operating the hysteresis comparator 534 is supplied to the positive power supply terminal 5343 and the negative power supply terminal 5344.

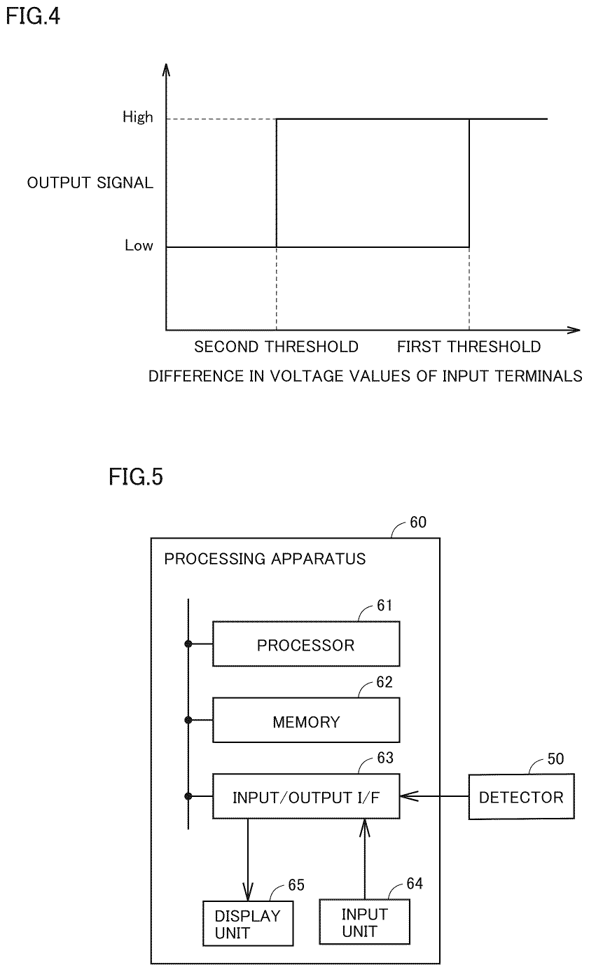

FIG. 4 is a diagram for explaining a signal output from the hysteresis comparator 534. The hysteresis comparator 534 outputs a High signal from the output terminal 5345 when the difference between the voltage value input from the non-inverting input terminal 5341 and the voltage value input from the inverting input terminal 5342 is greater than or equal to the first threshold. When this difference becomes greater than or equal to the first threshold and a High signal is output from the output terminal 5345, the High signal continues to be output until the difference becomes less than or equal to the second threshold. Further, the hysteresis comparator 534 outputs a Low signal when the difference becomes less than or equal to the second threshold. The hysteresis comparator 534, after the difference becomes less than or equal to the second threshold and a Low signal is output from the output terminal 5345, continues to output the Low signal unless the difference becomes greater than or equal to the first threshold. In one embodiment, the High signal corresponds to a first output, and the Low signal corresponds to a second output. In the CFD circuits 53 and 54, the switching from a Low signal to a High signal corresponds to outputting a pulse detection signal.

The processing apparatus 60 processes the energy spectrum detected by the detector 50. FIG. 5 is a diagram schematically showing the configuration of the processing apparatus 60.

The processing apparatus 60 includes, as main components, a processor 61, a memory 62, an input/output interface (I/F) 63, an input unit 64, and a display unit 65. These components are communicably connected to each other via a bus. The processing apparatus 60 is, for example, a computer. Note that the processing apparatus 60 does not need to be configured by a single computer, and may be configured by a plurality of computers.

The processor 61 is an example of an electric circuit and controls the operation of the processing apparatus 60 by executing a given program. The program executed by the processor 61 may be stored in the memory 62, or may be stored in a storage device external to the processing apparatus 60. The processor is, for example, a CPU (Central Processing Unit).

The memory 62 non-transiently stores a program to be executed by the processor 61 and energy spectrum data output from the detector 50. The memory 62 includes a volatile memory (for example, RAM (Random Access Memory)) and a non-volatile memory (for example, ROM (Read Only Memory), a hard disk drive, and a solid-state drive). Note that the database and/or the program may be stored in an external storage device accessible by the processor 61.

The input/output I/F 63 is an interface for exchanging various data between the processor 61 and the input unit 64 and the display unit 65 connected to the input/output I/F 63.

The input unit 64 includes, for example, at least one of a mouse, a keyboard, and a touch panel, and accepts operations for the processing apparatus 60.

The display unit 65 includes, for example, a liquid crystal display or an organic EL (Electro Luminescence) display, and displays information according to instructions from the processing apparatus 60. The information is, for example, energy spectrum data of the sample S output from the detector 50.

The processing apparatus 60 may control the XPS apparatus 100, or another control device (for example, a computer) may be connected to the XPS apparatus 100, and the control of the XPS apparatus 100 may be performed by this control device. The control of the XPS apparatus 100 is, for example, voltage adjustment and the like.

The XPS apparatus 100 generates energy spectrum data of electrons emitted from the sample S by measuring the incident position of electrons that have passed through the energy spectrometer 40 on the DLD 52 and the number of the electrons while changing the potential difference between the outer hemispherical electrode 41 and the inner hemispherical electrode 42.

### Comparative Example

Surface analysis is an analysis that clarifies the structure and composition of the surface and interface of a sample by applying a stimulus to the sample and analyzing the detected response. A method of surface analysis is, for example, XPS.

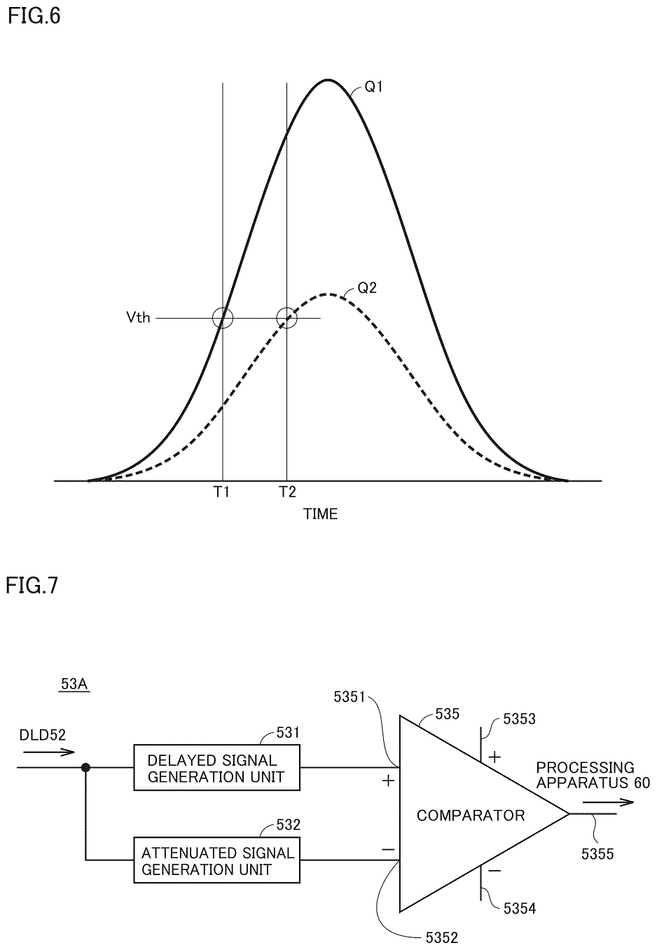

In surface analysis, including XPS, pulsed radiation or electrons emitted from a sample may be detected. As a method for detecting pulsed radiation or electrons emitted from a sample, there is a method of setting a predetermined threshold and detecting a pulse when the threshold is exceeded. FIG. 6 is a diagram for explaining a method of detecting a pulse by setting a threshold.

FIG. 6 shows a pulse Q1 and a pulse Q2 with a smaller amplitude than the pulse Q1. For example, when Vth is set as the threshold for detecting a pulse, the pulse is detected at time T1 for pulse Q1, and the pulse is detected at time T2 for pulse Q2. In pulses Q1 and Q2, although the magnitudes of the amplitudes are different, the positions of the peaks are the same. Therefore, it is preferable that the pulses be detected at the same timing. However, when a pulse is detected by setting the threshold Vth, time T1 and time T2 may not be the same timing.

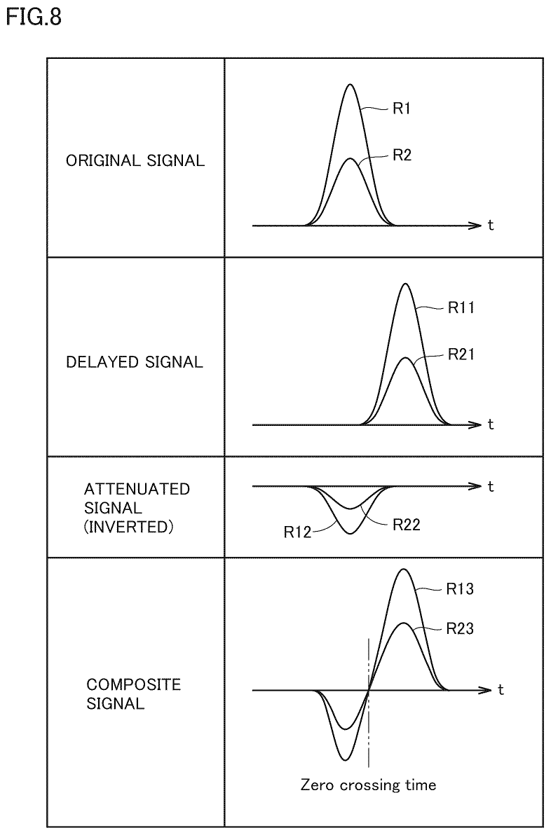

Therefore, a CFD circuit may be used when detecting pulsed radiation or electrons emitted from a sample. FIG. 7 is a schematic diagram for explaining the configuration of a CFD circuit according to a comparative example. FIG. 8 is a diagram for explaining a method of detecting a pulse using a CFD circuit.

With reference to FIG. 7, a CFD circuit 53A according to a comparative example includes a comparator 535 in addition to a delayed signal generation unit 531 and an attenuated signal generation unit 532.

The comparator 535 has a non-inverting input terminal 5351, an inverting input terminal 5352, a positive power supply terminal 5353, a negative power supply terminal 5354, and an output terminal 5355. The pulse generated by the delayed signal generation unit 531 is input to the non-inverting input terminal 5351. The pulse generated by the attenuated signal generation unit 532 is input to the inverting input terminal 5352. Power for operating the comparator 535 is supplied to the positive power supply terminal 5353 and the negative power supply terminal 5354.

The comparator 535 outputs a signal from the output terminal 5355 indicating that the voltages input to the non-inverting input terminal 5351 and the inverting input terminal 5352 are equal, when the voltage value input from the non-inverting input terminal 5351 and the voltage value input from the inverting input terminal 5352 become equal. The processing apparatus 60, upon receiving this signal, detects a pulse. Therefore, in the CFD circuit 53A, outputting a signal indicating that the voltages input to the non-inverting input terminal 5351 and the inverting input terminal 5352 are equal corresponds to outputting a detection signal.

The timing at which the CFD circuit 53A outputs a detection signal will be described with reference to FIG. 8. FIG. 8 shows the timing at which a detection signal is output when a pulse R1 and a pulse R2 with a smaller amplitude than the pulse R1 are input. First, the delayed signal generation unit 531 generates delayed signals R11 and R21, which are signals delayed by a predetermined time with respect to the original signals, pulse R1 and pulse R2. The generated delayed signals R11 and R21 are input to the non-inverting input terminal 5351. Further, the attenuated signal generation unit 532 generates attenuated signals R12 and R22, which are signals attenuated by a predetermined fraction with respect to the original signals, pulse R1 and pulse R2. The generated attenuated signals R12 and R22 are input to the inverting input terminal 5352.

The comparator 535 outputs a detection signal at the timing when the sign of a composite signal, which is a composite of the delayed signal and the attenuated signal, switches. The timing when the sign of the composite signal switches is the timing when the difference between the delayed signal and the attenuated signal becomes zero. Here, the timing when the sign of a composite signal R13, which is a composite of the delayed signal R11 and the attenuated signal R12, switches, and the timing when the sign of a composite signal R23, which is a composite of the delayed signal R21 and the attenuated signal R22, switches are the same timing. This timing is called the Zero crossing time and is known to be constant regardless of the magnitude of the amplitude. This timing corresponds to the timing when the pulse amplitude reaches a constant fraction.

In this way, by using the CFD circuit 53A, it is possible to output a detection signal at the timing when the pulse amplitude reaches a constant fraction, regardless of the amplitude of the radiation or electron pulses.

However, in the CFD circuit 53A, even when no pulse is being input, the voltage values of the non-inverting input terminal 5351 and the inverting input terminal 5352 may become equal, and a detection signal may be output.

In order to prevent a detection signal from being output when no pulse is being input in a CFD circuit, there is a method of applying an offset voltage to one of the input terminals. By applying an offset voltage to one of the input terminals, the difference in voltage applied to the two input terminals differs by the amount of the offset voltage, even in a state where no pulse is being input. Therefore, even in a state where no pulse is being input, the values of the voltages applied to the two input terminals do not become equal, so a detection signal is not output. However, when a pulse is input, the timing at which the detection signal is output shifts from the timing at which the value of the delayed signal of the input pulse and the value of the attenuated signal of the pulse become equal, by an amount corresponding to the value of the offset voltage.

Furthermore, in order to prevent a detection signal from being output when no pulse is being input in a CFD circuit, there is a method of providing a circuit for determining whether a pulse has been input. According to this method, the comparator outputs a detection signal when a pulse is input and the voltage values at the two terminals of the comparator become equal. Therefore, it is possible to prevent a detection signal from being output when no pulse is being input, and no deviation occurs between the timing at which the voltage values of the two terminals become equal and the timing at which the detection signal is output. However, it is necessary to provide a separate circuit for determining whether a pulse has been input, in addition to the CFD circuit. In particular, in order to detect a waveform with a short pulse width, which is a detection target in an XPS apparatus, an expensive circuit capable of processing electrical signals in a high-frequency region may be required. Therefore, the manufacturing cost of the CFD circuit may become high.

### Manufacturing Method of CFD Circuit According to the Present Embodiment

Therefore, the manufacturing method of a CFD circuit according to the present embodiment includes a step of providing a hysteresis comparator having two thresholds. It also includes a step of setting a voltage value equal to the threshold used for pulse detection, among the two thresholds, as an offset voltage. This makes it possible to prevent a detection signal from being output when no pulse is input, and to output a detection signal at the timing when the delayed signal and the attenuated signal become equal.

Furthermore, according to the manufacturing method of a CFD circuit of the present embodiment, there is no need to provide a circuit for determining whether a pulse has been input. Therefore, the manufacturing cost of the CFD circuit can be reduced.

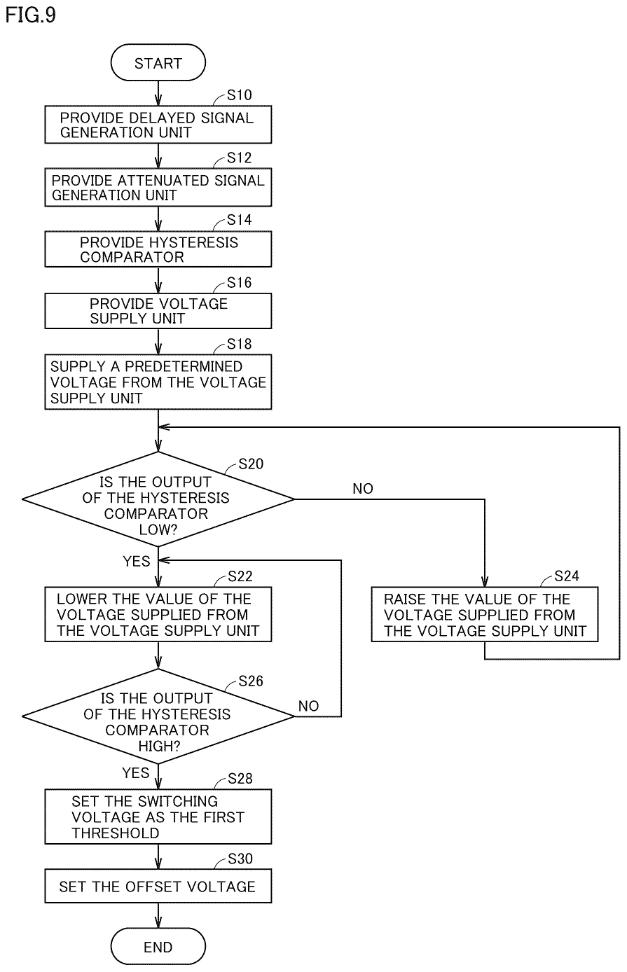

Hereinafter, a manufacturing method of the CFD circuits 53 and 54 according to the present embodiment will be described. FIG. 9 is a flowchart showing a method for manufacturing the CFD circuits 53 and 54. In one implementation, the process related to the manufacturing of the CFD circuits 53 and 54 in FIG. 9 is executed by a manufacturer (operator) during the manufacturing of the XPS 100. According to the method shown in this flowchart, a voltage equal to the first threshold can be used as the offset voltage. This allows the CFD circuits 53 and 54 to output a detection signal at the timing when the delayed signal and the attenuated signal become equal. Note that since the manufacturing method of the CFD circuit 54 is the same as the manufacturing method of the CFD circuit 53, a description thereof is omitted.

The first threshold and the second threshold are unique values for each hysteresis comparator. Individual differences exist in the first threshold and the second threshold. Therefore, in order to accurately supply a voltage value corresponding to the first threshold from the voltage supply unit 533 to the hysteresis comparator 534, it is necessary to set the voltage value supplied by the voltage supply unit 533 according to the following flowchart.

In step S10, an operator provides a delayed signal generation unit 531 in the CFD circuit 53. The delayed signal generation unit 531 generates a delayed signal by delaying an input pulse by a predetermined amount of time.

In step S12, the operator provides an attenuated signal generation unit 532 in the CFD circuit 53. The attenuated signal generation unit 532 generates an attenuated signal by attenuating an input pulse by a predetermined fraction.

In step S14, the operator provides a hysteresis comparator 534 in the CFD circuit 53.

In step S16, the operator provides a voltage supply unit 533 that supplies a voltage to the inverting input terminal 5342 of the hysteresis comparator 534.

In step S18, the operator applies a voltage of a predetermined magnitude to the inverting input terminal 5342 of the hysteresis comparator 534 using the voltage supply unit 533.

In step S20, the operator determines whether the output of the hysteresis comparator 534 is Low. If the output of the hysteresis comparator 534 is Low (YES in step S20), the process proceeds to step S22; otherwise (NO in step S20), the process proceeds to step S24.

In step S22, the operator lowers the value of the voltage supplied from the voltage supply unit 533.

In step S24, the operator raises the value of the voltage supplied from the voltage supply unit 533.

In step S26, the operator determines whether the output of the hysteresis comparator 534 is High. If the output of the hysteresis comparator 534 is High (YES in step S26), the process proceeds to step S28; otherwise (NO in step S26), the process returns to step S22.

In step S28, the operator sets the switching voltage, which is the value of the voltage supplied from the voltage supply unit 533 at the timing when the output of the hysteresis comparator 534 switched from Low to High in step S26, as the value of the first threshold of the hysteresis comparator 534.

In step S30, the operator sets the value of the first threshold set in step S28 as the offset voltage to be supplied by the voltage supply unit 533 to the hysteresis comparator 534. Thereafter, the operator ends the process of FIG. 9.

According to the flowchart described above, the operator can supply a voltage corresponding to the first threshold of the hysteresis comparator 534 from the voltage supply unit 533 to the hysteresis comparator 534. In this state, when a pulse is input to the CFD circuit 53, a detection signal can be output regardless of the magnitude of the amplitude of the pulse. Note that in the flowchart described above, the value of the first threshold was determined based on the output of the hysteresis comparator 534, but if the operator is aware of the value of the first threshold, the operator may set this value as the offset voltage in step S30 without executing steps S18 to S28.

Furthermore, in the flowchart described above, a voltage was applied in steps S18, S20, and S24 so that the output of the hysteresis comparator 534 becomes Low. If the output of the hysteresis comparator 534 is Low at the start of the flowchart described above, the operator does not need to execute the processes of steps S18, S20, and S24.

In the embodiment described above, the voltage supply unit 533 was connected to the inverting input terminal 5342 of the hysteresis comparator 534, but the present invention is not limited to this, and the voltage supply unit 533 may be connected to the non-inverting input terminal 5341. In this case, in the above step S16, the operator raises the value of the voltage supplied from the voltage supply unit 533, and in step S18, the operator lowers the value of the voltage supplied from the voltage supply unit 533.

The first threshold and the second threshold in the present embodiment are preferably set according to the environment in which the CFD circuit 53 is used. Therefore, it is preferable that a hysteresis comparator having a first threshold and a second threshold suitable for the environment is selected according to the environment in which the CFD circuit 53 is used. The environment in which the CFD circuit 53 is used includes, for example, the magnitude of noise generated in the CFD circuit 53 and the amplitude of the pulse detected by the CFD circuit 53.

Specifically, it is preferable that the difference between the first threshold and the second threshold in the present embodiment is larger than the noise input to the hysteresis comparator 534. By making the difference between the first threshold and the second threshold larger than the noise, it is possible to prevent the signal output from the hysteresis comparator 534 from switching due to noise and a detection signal from being output.

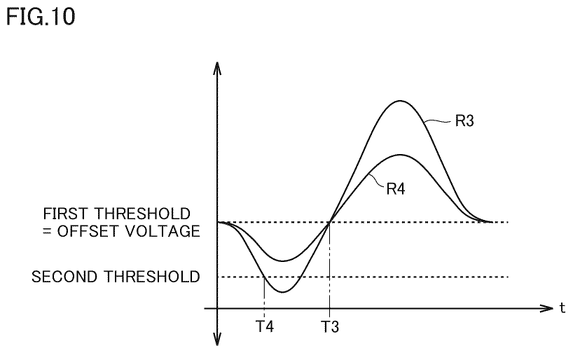

Furthermore, it is preferable that the first threshold and the second threshold in the present embodiment are of a magnitude such that the composite signal of the pulses can fall below the second threshold before the Zero crossing time. FIG. 10 is a diagram for explaining the difference between the first threshold and the second threshold.

With reference to FIG. 10, the offset voltage is set to be the same value as the first threshold by the manufacturing method of the CFD circuit 53 described above. Therefore, in a state where no signal is being input to the two input terminals of the hysteresis comparator 534, an offset voltage equal to the first threshold is input to the hysteresis comparator 534. Thus, the signal output from the hysteresis comparator 534 before a pulse is input is High.

As shown in FIG. 10, when a pulse is input to the hysteresis comparator 534, the composite signal input to the hysteresis comparator 534 becomes smaller, and increases over time. In FIG. 10, the Zero crossing time, which is the timing at which the detection signal is output, is indicated by time T3.

In FIG. 10, the composite signal R3 becomes less than or equal to the second threshold at time T4, which is before time T3. Therefore, after time T4, the signal output from the hysteresis comparator 534 is Low, and at the timing of time T3, the signal output from the hysteresis comparator 534 switches to High. Therefore, for the composite signal R3, since the output of the hysteresis comparator 534 switches from Low to High, the processing apparatus 60 can detect a pulse.

In FIG. 10, the composite signal R4 originates from a pulse with a smaller amplitude than the pulse of the composite signal R3. The composite signal R4, unlike the composite signal R3, does not become less than or equal to the second threshold before time T3. Therefore, the output of the hysteresis comparator 534 remains High from when the pulse is input until time T3, and no detection signal is output from the hysteresis comparator 534. Therefore, it is preferable to select a hysteresis comparator having a first threshold and a second threshold such that the difference in the voltage values applied to the two input terminals becomes less than or equal to the difference in magnitude between the first threshold and the second threshold after a pulse is input and before the pulse is detected.

In the present embodiment, an example was described in which the signal output from the delayed signal generation unit 531 is input to the non-inverting input terminal 5341, and the signal output from the attenuated signal generation unit 532 is input to the inverting input terminal 5342. However, the present invention is not limited to this, and the signal output from the delayed signal generation unit 531 may be input to the inverting input terminal 5342, and the signal output from the attenuated signal generation unit 532 may be input to the non-inverting input terminal 5341. Since the absolute value of the voltage output from the attenuated signal generation unit 532 becomes larger before the absolute value of the signal output from the delayed signal generation unit 531, in this case, a detection signal is output when the composite signal becomes less than or equal to the second threshold. In other words, the processing apparatus 60 detects a pulse at the timing when the signal output from the hysteresis comparator switches from a High signal to a Low signal.

In the present embodiment, the DLD 52 is configured to detect the position where an electron collides on a predetermined line, but the present invention is not limited to this, and the DLD may be configured to detect the position where an electron collides on a predetermined plane. In this case, four CFD circuits are connected to detect the arrival timing of pulses at both ends of a predetermined axis on the plane and at both ends of an axis orthogonal to the predetermined axis.

According to the manufacturing method of a CFD circuit of the present embodiment, it is possible to reduce the manufacturing cost of a CFD circuit that outputs a detection signal at a timing when the amplitude of an input pulse reaches a constant fraction.

In the description of the present embodiment, a CFD circuit provided in an XPS was taken as an example, but the manufacturing method according to the present embodiment is not limited to the manufacturing of a CFD circuit provided in an XPS. The manufacturing method in the present embodiment can be applied to the manufacturing of any CFD circuit for detecting the timing at which the pulse amplitude reaches a constant fraction, regardless of the magnitude of the pulse amplitude, and the apparatus in which the CFD circuit is provided is not limited.

### ASPECTS

It will be understood by those skilled in the art that the plurality of exemplary embodiments described above are specific examples of the following aspects.

(Item 1) A manufacturing method for a CFD circuit that detects pulses of electrons or radiation, the method comprising: a step of providing a delayed signal generation unit that generates a delayed signal by delaying the pulse by a predetermined time; a step of providing an attenuated signal generation unit that generates an attenuated signal by attenuating the pulse by a predetermined fraction; a step of providing a hysteresis comparator that includes two input terminals for receiving the delayed signal and the attenuated signal, has a first threshold and a second threshold smaller than the first threshold, outputs a first output when a difference between voltage values input to the two input terminals is greater than or equal to the first threshold, and outputs a second output when the difference between the voltage values input to the two input terminals is less than or equal to the second threshold; a step of providing a voltage supply unit that applies an offset voltage corresponding to the first threshold or the second threshold to the hysteresis comparator; and a step of setting the offset voltage, wherein the step of setting the offset voltage includes setting a voltage corresponding to the first threshold as the offset voltage when the delayed signal is input to a non-inverting input terminal of the two input terminals in the CFD circuit, and setting a voltage corresponding to the second threshold as the offset voltage when the delayed signal is input to an inverting input terminal of the two input terminals in the CFD circuit.

According to the manufacturing method described in Item 1, it is possible to reduce the manufacturing cost of a CFD circuit that outputs a detection signal at a timing when an input pulse amplitude reaches a constant fraction.

(Item 2) The manufacturing method according to Item 1, further comprising: when the delayed signal is input to the non-inverting input terminal of the two input terminals in the CFD circuit, a step of supplying a voltage from the voltage supply unit such that the second output is output; a step of changing the value of the voltage from the voltage supply unit and searching for a value of a switching voltage supplied from the voltage supply unit at a timing when the output switches from the second output to the first output; and a step of setting the value of the switching voltage as the first threshold.

According to the manufacturing method described in Item 2, it is possible to clarify the voltage value corresponding to the threshold used for pulse detection and apply a voltage corresponding to this value as an offset voltage to the hysteresis comparator.

(Item 3) The manufacturing method according to Item 1, further comprising: when the delayed signal is input to the inverting input terminal of the two input terminals in the CFD circuit, a step of supplying a voltage from the voltage supply unit such that the first output is output; a step of changing the value of the voltage from the voltage supply unit and searching for a value of a switching voltage supplied from the voltage supply unit at a timing when the output switches from the first output to the second output; and a step of setting the value of the switching voltage as the second threshold.

According to the manufacturing method described in Item 3, it is possible to clarify the voltage value corresponding to the threshold used for pulse detection and apply a voltage corresponding to this value as an offset voltage to the hysteresis comparator.

(Item 4) The manufacturing method according to any one of Items 1 to 3, wherein the voltage supply unit may be a DAC (Digital to Analog Converter).

According to the manufacturing method described in Item 4, the CFD circuit includes a DAC, and the voltage corresponding to the first threshold or the voltage corresponding to the second threshold is applied by the DAC.

(Item 5) The manufacturing method according to any one of Items 1 to 4, further comprising a step of selecting the hysteresis comparator according to an environment in which the CFD circuit is used.

According to the manufacturing method described in Item 5, a hysteresis comparator having a suitable first threshold and second threshold is selected according to the environment in which the CFD circuit is used.

(Item 6) The manufacturing method according to Item 5, wherein the environment in which the CFD circuit is used may include the amplitude of the pulse.

According to the manufacturing method described in Item 6, a hysteresis comparator having a suitable first threshold and second threshold is selected according to the magnitude of the amplitude of the pulse to be detected by the CFD circuit.

(Item 7) A pulse detector may comprise a CFD circuit manufactured by the manufacturing method of a CFD circuit according to any one of Items 1 to 6.

The pulse detector described in Item 7 can detect a pulse at a timing when an input pulse amplitude reaches a constant fraction. Furthermore, by providing the pulse detector with a CFD circuit manufactured by the manufacturing method of a CFD circuit according to any one of Items 1 to 6, the manufacturing cost of the pulse detector can be reduced.

(Item 8) The pulse detector according to Item 7 may further comprise a Delay line Detector.

According to the pulse detector described in Item 8, the position within the pulse detector where an electron has collided can be clarified by the DLD and the CFD circuit.

(Item 9) An X-ray photoelectron spectroscopy apparatus may comprise the pulse detector according to Item 7 or Item 8.

The X-ray photoelectron spectroscopy apparatus described in Item 9 can detect a pulse at a timing when an input pulse amplitude reaches a constant fraction. Furthermore, by providing the pulse detector of the X-ray photoelectron spectroscopy apparatus with a CFD circuit manufactured by the manufacturing method of a CFD circuit according to any one of Items 1 to 6, the manufacturing cost of the X-ray photoelectron spectroscopy apparatus can be reduced.

The embodiments disclosed herein should be considered in all respects as illustrative and not restrictive. The scope of the present disclosure is indicated by the claims rather than by the description of the embodiments above, and all changes that come within the meaning and range of equivalency of the claims are intended to be embraced therein. Furthermore, it is intended that each technology in the embodiments can be implemented alone or in combination with other technologies in the embodiments as much as possible, as necessary.

### REFERENCE SIGNS LIST

10 X-ray source, 20 lens, 30 slit, 31 entrance slit, 40 energy spectrometer, 41 outer hemispherical electrode, 42 inner hemispherical electrode, 50 detector, 51 micro-channel plate, 52 delay line detector, 53, 53A, 54 CFD circuit, 60 processing apparatus, 61 processor, 62 memory, 63 input/output interface (I/F), 64 input unit, 65 display unit, 100 XPS apparatus, 531 delayed signal generation unit, 532 attenuated signal generation unit, 533 voltage supply unit, 534 hysteresis comparator, 535 comparator, 5341, 5351 non-inverting input terminal, 5342, 5352 inverting input terminal, 5343, 5353 positive power supply terminal, 5344, 5354 negative power supply terminal, 5345, 5355 output terminal.

1. A manufacturing method for a CFD (Constant Fraction Discriminator) circuit that detects a pulse of an electron or radiation, the method comprising:
a step of providing a delayed signal generation unit that generates a delayed signal by delaying the pulse by a predetermined time;
a step of providing an attenuated signal generation unit that generates an attenuated signal by attenuating the pulse by a predetermined fraction;
a step of providing a hysteresis comparator that includes two input terminals for receiving the delayed signal and the attenuated signal, has a first threshold and a second threshold smaller than the first threshold, outputs a first output when a difference between voltage values input to the two input terminals is greater than or equal to the first threshold, and outputs a second output when the difference between the voltage values input to the two input terminals is less than or equal to the second threshold;
a step of providing a voltage supply unit that applies an offset voltage corresponding to the first threshold or the second threshold to the hysteresis comparator; and
a step of setting the offset voltage, wherein
the step of setting the offset voltage includes:
setting a voltage corresponding to the first threshold as the offset voltage when the delayed signal is input to a non-inverting input terminal of the two input terminals in the CFD circuit, and
setting a voltage corresponding to the second threshold as the offset voltage when the delayed signal is input to an inverting input terminal of the two input terminals in the CFD circuit.

2. The manufacturing method according to claim 1, further comprising, when the delayed signal is input to the non-inverting input terminal of the two input terminals in the CFD circuit:
a step of supplying a voltage from the voltage supply unit such that the second output is output;
a step of changing a value of the voltage from the voltage supply unit and searching for a value of a switching voltage supplied from the voltage supply unit at a timing when an output switches from the second output to the first output; and
a step of setting the value of the switching voltage as the first threshold.

3. The manufacturing method according to claim 1, further comprising, when the delayed signal is input to the inverting input terminal of the two input terminals in the CFD circuit:
a step of supplying a voltage from the voltage supply unit such that the first output is output;
a step of changing a value of the voltage from the voltage supply unit and searching for a value of a switching voltage supplied from the voltage supply unit at a timing when an output switches from the first output to the second output; and
a step of setting the value of the switching voltage as the second threshold.

4. The manufacturing method according to claim 1, wherein the voltage supply unit is a DAC (Digital to Analog Converter).

5. The manufacturing method according to claim 1, further comprising a step of selecting the hysteresis comparator according to an environment in which the CFD circuit is used.

6. The manufacturing method according to claim 5, wherein the environment in which the CFD circuit is used includes a magnitude of noise and an amplitude of the pulse.

7. A pulse detector comprising a CFD circuit manufactured by the manufacturing method according to claim 1.

8. The pulse detector according to claim 7, further comprising a Delay line Detector.

9. An X-ray photoelectron spectroscopy apparatus comprising the pulse detector according to claim 7.
